(19) United States
(12) Patent Application Publication
(10) Pub. No.: US 2014/0024208 A1
(43) Pub. Date: Jan. 23, 2014

(54) INTEGRATED CIRCUIT DEVICE INCLUDING LOW RESISTIVITY TUNGSTEN AND METHODS OF FABRICATION

(71) Applicants: MARTIN M. FRANK, DOBBS FERRY, NY (US); VIJAY NARAYANAN, NEW YORK, NY (US)

(72) Inventors: MARTIN M. FRANK, DOBBS FERRY, NY (US); VIJAY NARAYANAN, NEW YORK, NY (US)

(73) Assignee: INTERNATIONAL BUSINESS MACHINES CORPORATION, ARMONK, NY (US)

(21) Appl. No.: 13/558,805

(22) Filed: Jul. 26, 2012

Related U.S. Application Data
(63) Continuation of application No. 13/551,066, filed on Jul. 17, 2012.

(51) Int. Cl. H01L 21/28

(52) U.S. Cl. 438/592; 257/E21.19

(57) ABSTRACT

An integrated circuit device includes a semiconductor substrate and a gate electrode on the semiconductor substrate. The gate electrode structure includes an insulating layer of a dielectric material on the semiconductor substrate, an oxygen barrier layer on the insulating layer, and a tungsten (W) metal layer on the oxygen barrier layer. Also disclosed are methods for fabricating the device.

### CROSS REFERENCE TO RELATED APPLICATIONS

This application is a continuation application of and claims priority to U.S. application Ser. No. 13/551,066, filed on Jul. 17, 2012, incorporated herein by reference in its entirety.

### BACKGROUND

The present disclosure generally relates to integrated circuit devices including low resistivity metal and methods of manufacture.

To continue metal oxide semiconductor field effect transistor (MOSFET) gate stack scaling, various materials with high relative permittivity (high k dielectrics) and their integration issues have been widely studied. Hf-based high-k dielectrics with metal gates have been successfully implemented. However, according to the ITRS roadmap, further gate scaling is needed to simultaneously meet future performance and power requirements. It has become evident that only replacing the gate insulator, with no concurrent change of electrode material may not be sufficient for device scaling.

Tungsten is a metallization element with multiple uses in electronics, and in particular, in chip technology. Examples of such uses include, but are not limited to, using the tungsten plug fill process for filling contacts and vias in front- and back-end metallization schemes, using tungsten as an interconnect material, using tungsten as a component of the metal-oxide-semiconductor field-effect transistor (MOSFET) gate stack, and using tungsten as a component of the dynamic random access memory (DRAM) gate stack, among others.

In DRAM applications, conventional tungsten polycide (WSiₓ) gate stacks have previously been adopted for use in earlier DRAM generations However, these materials are generally not practical for further gate scaling since sheet resistance is too high. Simply increasing the thickness of the stack structure with WSix to reduce sheet resistance results in other issues such as etch profile, BPSG void formation, increased parasitic capacitance, among others. Moreover, sheet resistance rapidly increases as the width of the word line is decreased due to scaling.

To overcome these problems, tungsten polymetal gate structures that require a barrier layer have been proposed, e.g., W/TiNx/polysilicon or W/TaNx/polysilicon. However, when depositing tungsten onto TiN or TaN, small-grain, high-resistivity tungsten is often formed. Since grain boundary scattering of electrons in tungsten is one of the main factors limiting electrical conductivity (i.e., increasing resistivity), large tungsten grain size is therefore generally desired. Special treatments before and during tungsten deposition and via multi-step deposition procedures can be used to increase grain size and reduce resistivity. However, such procedures may reduce manufacturing throughput and increase cost.

### SUMMARY

According to an embodiment, a method of fabricating a layered structure comprises depositing a silicon layer onto an underlying layer; depositing an oxygen barrier layer overlaying the silicon layer, wherein the oxygen barrier layer consists essentially of tantalum aluminum nitride (TaAlN) or titanium aluminum nitride (TiAlN); and depositing a tungsten layer deposited on the oxygen barrier layer

In another embodiment, a method of fabricating a semiconductor device comprises depositing a dielectric layer overlaying a semiconductor substrate; depositing a silicon layer overlaying the dielectric layer; depositing an oxygen barrier layer onto the silicon layer, wherein the oxygen barrier layer consists essentially of tantalum aluminum nitride or titanium aluminum nitride; and depositing a tungsten layer on the oxygen barrier layer.

In another embodiment, a method of fabricating a semiconductor device comprises depositing a high k dielectric layer overlaying a semiconductor substrate, wherein the high k dielectric layer comprises a material having a dielectric constant greater than 4.0; depositing a metal layer overlaying the high k dielectric layer; depositing a silicon layer overlaying the metal layer; depositing an oxygen barrier layer deposited onto the silicon layer, wherein the oxygen barrier layer consists essentially of tantalum aluminum nitride or titanium aluminum nitride; and depositing a tungsten layer deposited onto the oxygen barrier layer.

Additional features and advantages are realized through the techniques of the present disclosure. Other embodiments and aspects of the disclosure are described in detail herein and are considered a part of the claimed disclosure. For a better understanding of the disclosure with advantages and features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a cross sectional view of a gate electrode structure in accordance with the present disclosure.

FIG. 2 graphically illustrates capacitance as a function of gate bias during a bidirectional gate bias sweep (from −1.5 V to +1.0 V and back to −1.5 V) for various gate electrodes in accordance with the present disclosure and comparative gate electrodes.

FIG. 3 graphically illustrates the areal gate leakage current at a gate bias of +1 V as a function of capacitance equivalent thickness (CET) for various gate electrodes in accordance with the present disclosure and comparative gate electrodes.

### DETAILED DESCRIPTION

Disclosed herein is a low resistivity metal gate electrode structure including a low resistivity tungsten metal layer, an oxygen barrier layer and a silicon layer, wherein the oxygen barrier layer is formed of TaAlN or TiAlN and is intermediate the tungsten metal layer and the silicon layer. Advantageously, the gate electrode structure of the present disclosure has been found to be thermally stable even after annealing at 1000° C. Moreover, the sheet resistivity of the tungsten metal layer is about 11 to 15 ohm/square at a thickness of about 125 Angstrom, which was more than 50% lower than a similar gate electrode structure including TiN or TaN instead of TaAlN or TiAlN.

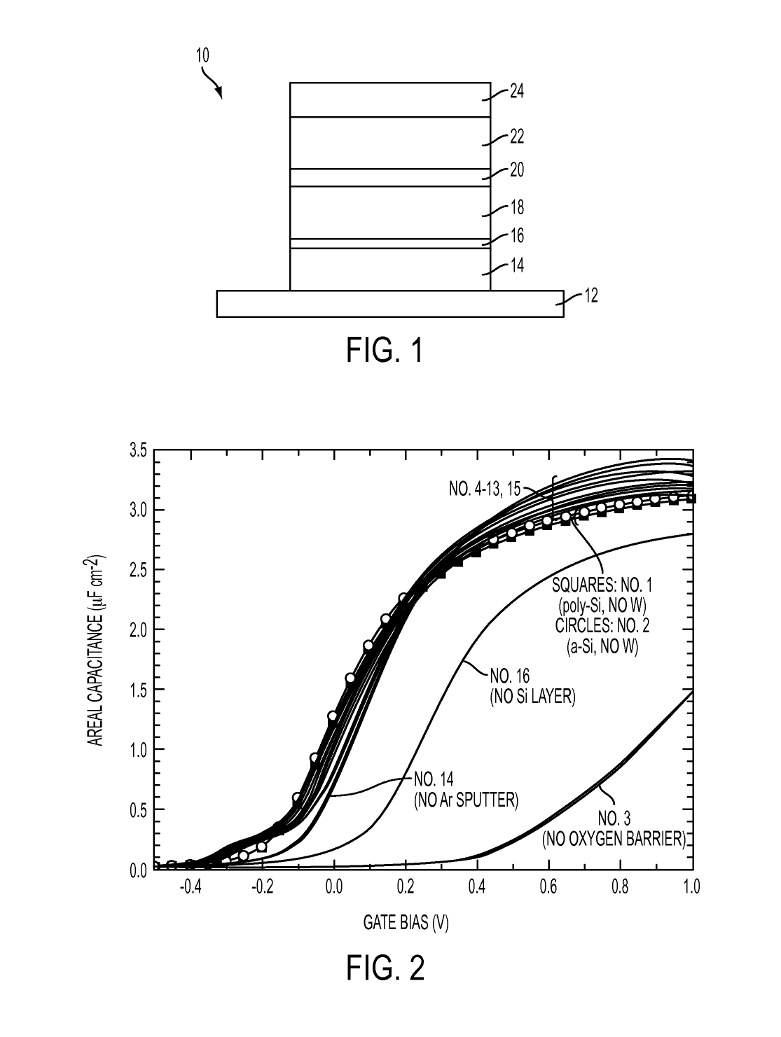

Referring now to FIG. 1, the gate electrode structure 10 generally includes a semiconductor substrate 12 upon which the gate electrode structure is fabricated. The semiconductor substrate 10 can be silicon. However, also other semiconductor materials such as germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials are possible.

The gate electrode structure 10 can further include an oxide or oxynitride layer (not shown), which is also referred to as the interfacial layer upon which a dielectric layer 14 is deposited. For example, the process step for forming an oxide layer may include wet chemical oxidation. An exemplary wet chemical oxidation process may include treating the cleaned semiconductor surface (such as a semiconductor surface treated with hydrofluoric acid) with a mixture of ammonium hydroxide, hydrogen peroxide and water (in a 1:1:5 ratio) at 65° C. Alternately, the oxide layer can also be formed by treating the HF-last semiconductor surface in ozonated aqueous solutions, with the ozone concentration usually varying from, but not limited to: 2 parts per million (ppm) to 40 ppm. The oxide layer helps minimize mobility degradation in the substrate semiconductor layer 12 due to the high-k dielectric material. In case the substrate semiconductor layer is a silicon layer, the oxide layer may be a silicon oxide layer. Typically, the thickness of the oxide layer is from 5 Angstrom to 15 Angstrom, although lesser and greater thicknesses are also contemplated herein. Other methods of forming an interfacial oxide layer, as well as other interfacial layers, are also contemplated herein.

The dielectric layer 14 generally includes a dielectric metal oxide. In one embodiment, the dielectric layer comprises a high k dielectric material having a dielectric constant that is greater than the dielectric constant of silicon oxide. In one embodiment, the dielectric layer has a dielectric constant of greater than 4.0, typically greater than 10, as measured in vacuum. Examples of such dielectric materials having a dielectric constant of greater than 4.0 include, but are not limited to silicon nitride, silicon oxynitride, metal oxides, metal nitrides, metal oxynitrides and/or metal silicates. In one embodiment, the dielectric layer 14 comprises HfO₂, ZrO₂, Al₂O₃, TiO₂, La₂O₃SrTiO₃, LaAlO₃, Y₂O₃ or multilayered stacks thereof. In another embodiment of the disclosure, the dielectric layer 14 is a Hf-based gate dielectric including HfO₂, hafnium silicate and hafnium silicon oxynitride, optionally comprising additional metal ions such as, for example, Al, La, Dy, Sr, or Ba. Structures without a high-k dielectric layer, instead including, e.g., an oxide such as silicon oxide (SiO₂) or an oxynitride such as silicon oxynitride (SiON), are also contemplated herein.

The dielectric layer may be formed by methods well known in the art including, for example, chemical vapor deposition (CVD), atomic layer deposition (ALD), molecular beam deposition (MBD), pulsed laser deposition (PLD), liquid source misted chemical deposition (LSMCD), sputter deposition, and the like.

The thickness of the as deposited high k gate dielectric 14 may vary depending on the dielectric material employed as well as the process used to form the same. Typically, the thickness of the as deposited high k gate dielectric 14 is from 5 Angstrom to 200 Angstrom, with a thickness from 10 Angstrom to 100 Angstrom being even more typical. If the gate dielectric layer 14 is silicon dioxide or silicon oxynitride, the thickness of the gate dielectric layer would include the thickness of the relatively thin interfacial oxide layer.

An optional thin metal layer 16, optionally comprising titanium nitride (TiN) or tantalum nitride (TaN), is then deposited onto the dielectric layer 14. Layer 16 typically has a layer thickness of less than or equal to 100 Angstrom. Layer 16 can be formed by a chemical vapor deposition process, e.g., by atomic layer deposition, or by any other deposition process.

After deposition of the thin metal layer 16, a silicon layer 18 is deposited. The silicon layer can be amorphous silicon (a-polysilicon) or may be polycrystalline silicon (polysilicon) and may be deposited by chemical vapor deposition process or other appropriate process. The silicon layer typically has a thickness of about 30 Angstrom to about 1000 Angstrom.

The surface of the silicon layer may then be subjected to a cleaning process to remove any oxide layer that may have formed on the silicon layer. For example, the silicon layer may be exposed to argon sputtering process for a period of time effective to remove about 10 Angstrom of the silicon layer, although higher or lower amounts of the silicon layer can be removed. Alternatively, the silicon layer may be exposed to a wet-chemical cleaning process, optionally including hydrofluoric acid.

The oxygen barrier layer 20 is then deposited onto the silicon layer 18. The oxygen barrier layer is a material selected from the group consisting of titanium aluminum nitride (TiAlN) and tantalum aluminum nitride (TaAlN), which is commonly deposited by physical vapor deposition, sputtering, thermal chemical vapor deposition, or plasma enhanced chemical vapor deposition processes. The aluminum content typically ranges from about 5 to about 40 atom % based on the total composition. An appropriate nitrogen content typically can be between about 10 and 50 atom %.

Optionally, the oxygen barrier layer may be subjected to air exposure or any other oxidizing treatment to introduce oxygen atoms as may be desired for some applications. The oxygen barrier layer 20 is typically at a thickness of 10 Angstrom to 500 Angstrom, and in other embodiments, a thickness from 25 Angstrom to 200 Angstrom.

The tungsten layer 22 can be deposited onto the oxygen barrier layer 20. The oxygen barrier layer 20 allows for the formation of much larger tungsten grains than, for example, on a TiN or TaN layer. As a result, lower grain boundary scattering can be expected resulting in lower sheet resistance.

The tungsten layer can optionally also contain smaller amounts of other elements, either immediately after tungsten deposition or after device fabrication, where the amount of other elements such as for example nitrogen, oxygen, titanium, or tantalum, or of any other element, preferably is lower than about 10 atom percent. The tungsten layer may have any thickness. For most applications, it should measure approximately 10 to 1000 Angstrom, and preferably approximately 50 to 500 Angstrom, in thickness.

An optional capping layer 24 can be deposited onto the tungsten layer 22. The capping layer can be made of any material. For many applications, it is preferable for the optional capping layer to comprise an insulating compound such as silicon nitride (Si₃N₄), aluminum oxide, or hafnium oxide, and for it to measure approximately 10 to 500 Angstrom in thickness. The capping layer may be formed by a deposition process, e.g., atomic layer deposition, PECVD (plasma-enhanced CVD), MOCVD (metallorganic CVD), MLD (molecular layer deposition), RTCVD (rapid thermal CVD), ALD, sputtering, or any other deposition method. Chemical vapor deposition processes are typically performed at elevated temperatures. For example, RTCVD of silicon nitride films may typically be performed at temperatures greater than 500° C. Physical deposition processes such as sputtering are often performed at lower temperatures, for example at room temperature.

The device structure may be subjected to one or multiple annealing processes. For example, one typical type of anneal will expose the substrate to temperatures greater than about 600° C. to about 1100° C. for a period a less than a minute, typically less than 10 seconds. Another typical type of anneal will expose the substrate to temperatures of 300° C. to about 600° C. for a longer period of time in a hydrogen atmosphere such as forming gas. Yet another typical type of anneal will expose the substrate to temperatures greater than about 1000° C. to about 1400° C. for a period a less than 20 milliseconds.

The following examples are presented for illustrative purposes only, and are not intended to limit the scope of the disclosure.

### Examples

In these examples, numerous comparative tungsten metal gate electrodes and tungsten metal gate electrodes in accordance with the present disclosure were fabricated on silicon semiconductor substrates and tungsten sheet resistivity measured. The structures of the gate electrodes generally included a tungsten metal layer, an oxygen barrier layer and a silicon layer, as provided in Table 1.

The surfaces of the substrates were first chemically treated to form an interfacial layer by chemical oxidation, followed by an anneal in an NH₃ ambient, followed by HfO₂ deposition at a thickness of 22 Angstrom and followed by lanthanum deposition at a thickness of about 4 Angstrom. A layer of TiN at a thickness of between 30 and 40 Angstrom was then deposited onto the HfO₂ layer. The silicon layer (e.g., amorphous silicon (a-Si) or polysilicon (poly-Si)) was then deposited by rapid thermal chemical vapor deposition (RTCVD) onto the high k dielectric layer. The deposited silicon surface was then treated, where indicated, to an argon sputter process (50 W, 360 seconds). The oxygen barrier layer, the tungsten metal layer, and a capping layer were then deposited as indicated. The electrode structures were then processed further to form metal-oxide-semiconductor capacitors (MOSCAPS), including an anneal at 1000° C. for 5 seconds and an exposure to a forming gas atmosphere at 475° C. for 30 minutes. Sheet resistance (Rs) was measured after deposition of the tungsten metal layer; after subsequent capping with a Si₃N₄ layer, and after annealing. The samples are described in Table 1 below. Examples 1 to 5 are comparative examples. The results are provided in Table 2 below.

TABLE 1

| Ex- | | | Oxygen | Post- | | |
|---|---|---|---|---|---|---|
| ample | RTCVD | Ar | Barrier | barrier | | RTCVD |
| No. | Si | Sputter | Layer | air break | Metal | Si₃N₄ |
| 1* | poly-Si | none | none | n/a | none | none |
| | [1000 Å] | | | | | |
| 2* | a-Si | none | none | n/a | none | none |
| | [1000 Å] | | | | | |
| 3* | a-Si | Ar | none | n/a | W | Si₃N₄ |
| | [200 Å] | Sputter | | | [125 Å] | [200 Å] |
| 4* | a-Si | Ar | TiN | no | W | Si₃N₄ |
| | [200 Å] | Sputter | [50 Å] | | [125 Å] | [200 Å] |
| 5* | a-Si | Ar | TaN | no | W | Si₃N₄ |
| | [200 Å] | Sputter | [50 Å] | | [125 Å] | [200 Å] |
| 6 | a-Si | Ar | TaAlN 16% Al | no | W | Si₃N₄ |
| | [200 Å] | Sputter | [50 Å] | | [125 Å] | [200 Å] |
| 7 | a-Si | Ar | TaAlN 16% Al | yes | W | Si₃N₄ |
| | [200 Å] | Sputter | [100 Å] | | [125 Å] | [200 Å] |
| 8 | a-Si | Ar | TaAlN 16% Al | no | W | Si₃N₄ |
| | [200 Å] | Sputter | [100 Å] | | [125 Å] | [200 Å] |
| 9 | a-Si | Ar | TaAlN 16% Al | yes | W | Si₃N₄ |
| | [200 Å] | Sputter | [50 Å] | | [125 Å] | [200 Å] |
| 10 | a-Si | Ar | TaAlN 27% Al | no | W | Si₃N₄ |
| | [200 Å] | Sputter | [50 Å] | | [125 Å] | [200 Å] |
| 11 | a-Si | Ar | TaAlN 27% Al | yes | W | Si₃N₄ |
| | [200 Å] | Sputter | [50 Å] | | [125 Å] | [200 Å] |
| 12 | a-Si | Ar | TaAlN 27% Al | no | W | Si₃N₄ |
| | [200 Å] | Sputter | [100 Å] | | [125 Å] | [200 Å] |
| 13 | a-Si | Ar | TaAlN 27% Al | yes | W | Si₃N₄ |
| | [200 Å] | Sputter | [100 Å] | | [125 Å] | [200 Å] |
| 14 | a-Si | none | TaAlN 27% Al | no | W | Si₃N₄ |
| | [200 Å] | | [100 Å] | | [125 Å] | [200 Å] |
| 15 | a-Si | Ar | TaAlN 27% Al | no | W | Si₃N₄ |
| | [114 Å] | Sputter | [100 Å] | | [125 Å] | [200 Å] |
| 16 | none | none | TaAlN 27% Al | no | W | Si₃N₄ |
| | | | [100 Å] | | [125 Å] | [200 Å] |

*Comparative examples

TABLE 2

| | | Post Capping | |
|---|---|---|---|
| | | (Si₃N₄) | Post Anneal |
| Example No. | Rs (ohm/sq) | Rs (ohm/sq) | Rs (ohm/sq) |
| 1* | 316 | 349 | 65-90 |
| 2* | 379 | 410 | 75 |
| 3* | 12.3 | 31.6 | 26.7 |
| 4* | 33 | 38.1 | 38.3 |
| 5* | 31.8 | 35.3 | 32.6 |
| 6 | 13.05 | 12.3 | 12.15 |
| 7 | 14.6 | 15 | 14.75 |
| 8 | 12.7 | 12.3 | 11 . . . 5 |
| 9 | 14.5 | 13.7 | 13.3 |
| 10 | 12.4 | 12.2 | 12 |
| 11 | 14.4 | 14.8 | 14.2 |
| 12 | 12.35 | 11.9 | 11.95 |
| 13 | 14 | 13 | 13.4 |
| 14 | 12.4 | 12.2 | 12.1 |
| 15 | 12.3 | 11/6 | 11/9 |
| 16 | 12.4 | 12.2 | 12 |

*comparative examples

As demonstrated in the comparative example 3 above, sheet resistance after tungsten deposition directly onto the silicon layer, after silicon nitride deposition at 700° C., and after annealing at 1000° C. were about 12, 32, and 27 Ohms/square, respectively. The marked increase in resistivity after subjecting the gate electrode structure to the elevated temperatures provided during the RTCVD of silicon nitride may be due to formation of tungsten silicide (i.e., WSi₂), causing morphological degradation of the film.

As for comparative examples 4 and 5, the use of TaN and TiN as the oxygen barrier layer resulted in relatively high resistivity of 32-33 ohms/square after tungsten deposition, which may be indicative of small grain formation.

In contrast, the gate electrode structures of examples 6-15, which are in accordance with the present disclosure, were unaffected by the temperatures and conditions employed during RTCVD of the nitride layer as well as during annealing and exhibited consistently lower resitivities of about 12-15 ohms/square with minimal variation. The low resistivities are indicative of a large grain tungsten structure provided by the use of the oxygen barrier layer.

FIG. 2 graphically illustrates capacitance as a function of gate bias during a bidirectional gate bias sweep (from −1.5 V to +1.0 V and back to −1.5 V) for various gate electrodes in accordance with the present disclosure and comparative gate electrodes. Comparative examples 1 and 2 are representative of metal-inserted poly-Si stack (MIPS) gate electrodes that are in use in some 32 and 28 nm logic CMOS technologies. Comparative example 3 is of poor quality due to the lack of an oxygen barrier layer, likely resulting in formation of tungsten silicide (i.e., WSi₂), causing morphological degradation of the film. Comparative example 16 has no Si layer separating the TaAlN layer from the TiN layer, resulting in an often undesirable change in flatband voltage vs. comparative examples 1 and 2. All other examples, including 6 to 15 which are in accordance with the present disclosure, desirably feature capacitance-voltage characteristics that are much closer to those of comparative examples 1 and 2. Example 14 without Ar sputter features capacitance-voltage characteristics in the negative gate bias range that are closer to ideality (i.e., there is no signal near −0.2 to 0.3 V) than what is observed for examples 4-13 and 15 with Ar sputter. This may indicate a lower density of trap states, e.g., at the channel/gate dielectric interface when Ar sputter is omitted, however this may be due to non-optimized Ar sputter process conditions and is not intended to suggest that Ar sputter is detrimental.

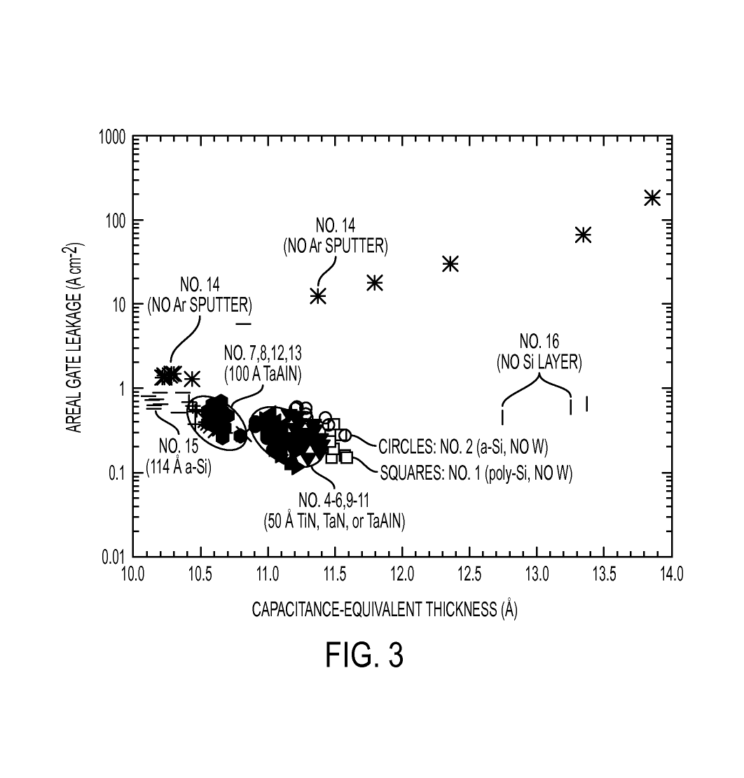

FIG. 3 graphically illustrates the areal gate leakage current at a gate bias of +1 V as a function of capacitance equivalent thickness (CET) for various gate electrodes (showing examples 1-2 and 4-16 only; example 3 omitted due to poor capacitance-voltage characteristics) in accordance with the present disclosure and comparative gate electrodes. Comparative example 16 without Si layer separating the TaAlN layer from the TiN layer undesirably has substantially higher CET than comparative examples 1 and 2. Example 14 without Ar sputter for some of the fabricated devices desirably features lower CET than comparative examples 1 and 2, with slightly higher areal gate leakage current, while both CET and areal gate leakage current are increased for some other of the fabricated devices, indicating yield issues due to native SiO₂ being present prior to TaAlN deposition in the absence of Ar sputter. All other examples, including 6 to 13 and 15 which are in accordance with the present disclosure, desirably feature similar or lower CET than comparative examples 1 and 2, with similar or only slightly higher areal gate leakage current.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the invention and the practical application, and to enable others of ordinary skill in the art to understand the disclosure for various embodiments with various modifications as are suited to the particular use contemplated.

1. A method of fabricating a layered structure, said method comprising:
depositing a silicon layer onto an underlying layer;
depositing an oxygen barrier layer on the silicon layer, wherein the oxygen barrier layer consists essentially of tantalum aluminum nitride (TaAlN) or titanium aluminum nitride (TiAlN); and
depositing a tungsten layer deposited on the oxygen barrier layer.

2. The method of claim 1, further comprising:
depositing a metal layer underlying the silicon layer; and
depositing a high k dielectric layer underlying the metal layer, wherein the high k dielectric layer comprises a material having a dielectric constant greater than 4.0.

3. The method of claim 2, wherein the metal layer comprises at least one of titanium nitride (TN) and tantalum nitride (TaN).

4. The method of claim 2, wherein the high k dielectric layer is a Hf-based dielectric.

5. The method of claim 1, wherein the silicon layer comprises at least one of polycrystalline silicon or amorphous polysilicon.

6. The method of claim 1, wherein said oxygen barrier layer has an aluminum content in an amount effective to provide said tungsten layer with a sheet resistivity of about 11 to about 15 ohm/square as measured at a thickness of about 125 Angstroms.

7. The method of claim 1, wherein said oxygen barrier layer is subject to surface oxidation.

8. The method of claim 1, wherein the silicon layer has a thickness of 100 to 1000 Angstrom, the oxygen barrier layer has a thickness of 25 to 200 Angstrom, and the tungsten layer has a thickness of 50 to 500 Angstrom.

9. The method of claim 1, further comprising depositing a capping layer overlaying the tungsten layer.

10. The method of claim 1, wherein the tungsten layer comprises tungsten nitride.

11. The method of claim 2, further comprising annealing the layered structure at a temperature greater than 600° C., wherein a resistivity of the tungsten layer remains substantially the same compared to a resistivity of the tungsten metal layer prior to annealing.

12. A method of fabricating a semiconductor device comprising:
depositing a dielectric layer overlaying a semiconductor substrate;
depositing a silicon layer overlaying the dielectric layer;
depositing an oxygen barrier layer onto the silicon layer, wherein the oxygen barrier layer consists essentially of tantalum aluminum nitride or titanium aluminum nitride; and
depositing a tungsten layer on the oxygen barrier layer.

13. The method of claim 12, wherein the semiconductor substrate comprises silicon.

14. The method of claim 12, further comprising depositing a capping layer overlaying said tungsten layer.

15. The method of claim 14, wherein the capping layer is silicon nitride.

16. The method of claim 12, wherein the tungsten layer comprises tungsten nitride.

17. The method of claim 12, wherein the dielectric layer comprises at least one of silicon oxide and silicon oxynitride.

18. The method of claim 12, wherein the silicon layer comprises polycrystalline silicon or amorphous polysilicon.

19. The method of claim 12, further comprising annealing the device at a temperature greater than 600° C., wherein a resistivity of the tungsten layer remains substantially the same compared to a resistivity of the tungsten metal layer prior to annealing.

20. A method of fabricating a semiconductor device comprising:
depositing a high k dielectric layer overlaying a semiconductor substrate, wherein the high k dielectric layer comprises a material having a dielectric constant greater than 4.0;
depositing a metal layer overlaying the high k dielectric layer;
depositing a silicon layer overlaying the metal layer;
depositing an oxygen barrier layer deposited onto the silicon layer, wherein the oxygen barrier layer consists essentially of tantalum aluminum nitride or titanium aluminum nitride; and
depositing a tungsten layer deposited onto the oxygen barrier layer.

21. The method according to claim 20, further comprising:
depositing a capping layer onto the tungsten layer.

22. The method according to claim 21, wherein the capping layer is silicon nitride.

23. The method according to claim 20, further comprising:
depositing an interfacial layer intermediate the semiconductor substrate and the high k dielectric layer.

24. The method according to claim 20, further comprising annealing the device at a temperature greater than 600° C., wherein a resistivity of the tungsten layer remains substantially the same compared to a resistivity of the tungsten metal layer prior to annealing.

25. The method according to claim 20, wherein the silicon layer has a thickness of 100 to 1000 Angstrom, the oxygen barrier layer has a thickness of 25 to 200 Angstrom, and the tungsten layer has a thickness of 50 to 500 Angstrom.
